(19) United States
(12) Patent Application Publication
(10) Pub. No.: US 2014/0029209 A1
(43) Pub. Date: Jan. 30, 2014

(54) POWER MANAGEMENT SYSTEM

(71) Applicant: HON HAI PRECISION INDUSTRY CO., LTD., New Taipei (TW)

(72) Inventors: HSIEN-CHUAN LIANG, New Taipei (TW); CHIH-CHUNG SHIH, New Taipei (TW); YUNG-CHIEH CHEN, New Taipei (TW)

(73) Assignee: HON HAI PRECISION INDUSTRY CO., LTD., New Taipei (TW)

(21) Appl. No.: 13/954,924

(22) Filed: Jul. 30, 2013

(30) Foreign Application Priority Data
Jul. 30, 2012 (TW) 101127512

(51) Int. Cl. H05K 7/14

(52) U.S. Cl. CPC H05K 7/14
USPC 361/729

(57) ABSTRACT

A power management system includes a main controller, a pair of supporting frames extending from the main controller, and a number of mobile modules removably mounted on the supporting frames. The main controller receives power from an external power source. Each of the mobile modules is connected to a load and electrically connected to the main controller via the supporting frame. The main controller provides power to the load via the corresponding mobile module. Each of the mobile modules presets a power limit according to a rated power of the load connected to the mobile module and cuts off an electrical connection with the load when an operating power of the load is greater than the power limit.

### BACKGROUND

1. Technical Field

The present disclosure relates to power technologies, and particularly, to a power management system of a server.

2. Description of Related Art

Generally, a server includes a number of computers and a power distribution unit (PDU) providing power to the computers. The PDU includes a number of power interfaces correspondingly connected to the computers to provide power. However, the PDU usually includes only one main controller to control power and execute a power-off protection for all the computers. The main controller cannot separately set a power limit for each of the computers and execute the power-off protection as well. Thus, if a low-powered computer is cut off by the main controller due to overload, other high-powered computers are affected at the same time.

Therefore, it is desirable to provide a means which can overcome the above-mentioned problem.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments.

FIG. 1 is an isometric view of a power management system in accordance with an exemplary embodiment of the present disclosure.

FIG. 2 is a circuit diagram of the power management system of FIG. 1.

FIG. 3 is a serial connection diagram of the mobile modules of FIG. 1.

FIG. 4 is a parallel connection diagram of the mobile module of FIG. 1.

### DETAILED DESCRIPTION

Embodiments of the disclosure are described with reference to the drawings.

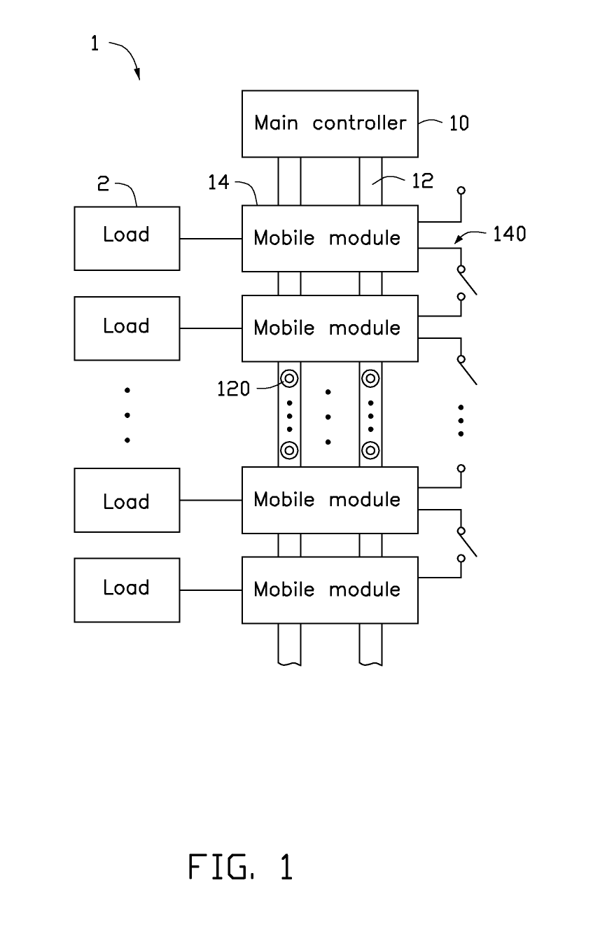

FIG. 1 is an isometric view of a power management system 1 in accordance with an exemplary embodiment of the present disclosure, The power management system 1 includes a main controller 10, a pair of supporting frames 12, and a number of mobile modules 14. The supporting frame 12 extends from the main controller 10 and electrically connects with the mobile modules 14. The mobile modules 14 are removably mounted on the supporting frame 12 and electrically connected to the main controller 10 via the supporting frame 12. Each of the mobile modules 14 includes a rotating switch 140. Two adjacent mobile modules 14 can connect with each other via the rotating switch 140. Each of the mobile modules 14 correspondingly connects with a load 2. The main controller 10 connects with an external power source 3 to receive power. The main controller 10 provides power to each of the loads 2 via the corresponding mobile module 14.

The main controller 10 presets a total power limit according to all the loads 2 connected to the main controller 10 and cuts off an electrical connection between the loads 2 and the external power source 3 when the total power of all the loads 2 is greater than the total power limit.

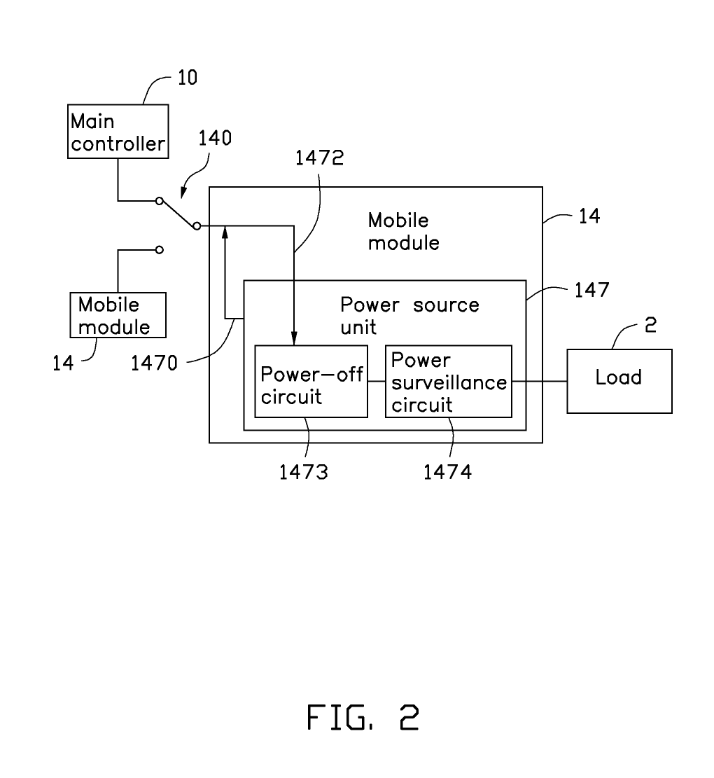

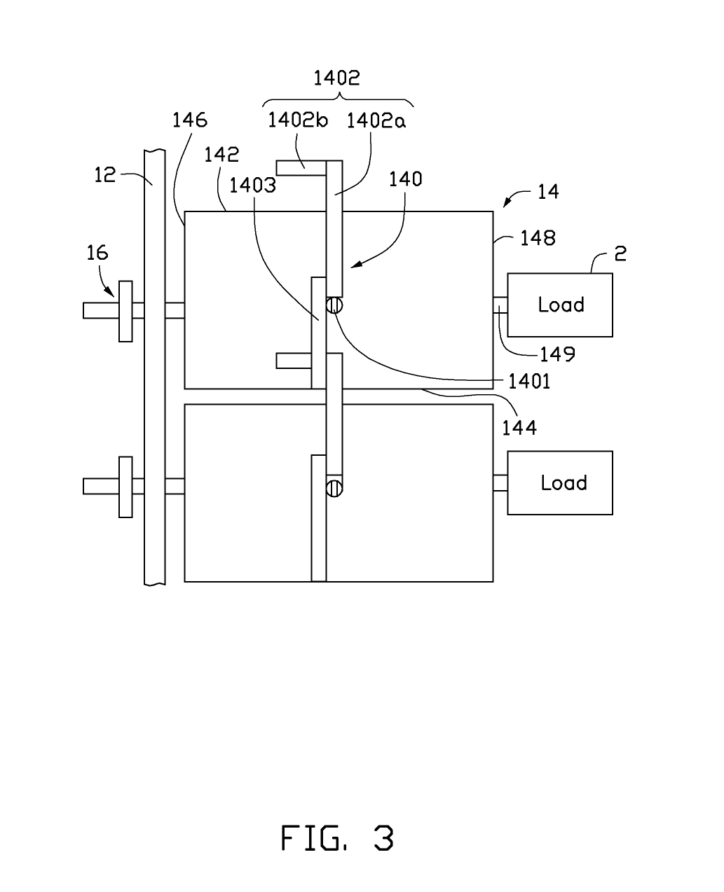

FIGS. 2 and 3 show that each of the supporting frames 12 defines a number of evenly spaced fastening holes 120. The fastening holes 120 are defined on the different supporting frames 12 and are aligned with each other. Each of the mobile modules 14 is fastened to the fastening holes 120 via at least one screw 16. In this embodiment, the supporting frames 12 are a pair of rails parallel to each other. The mobile modules 14 are electrically connected to the supporting frame 12 via the screw 16. In the other embodiment, the mobile modules 14 are electrically connected to the main controller 10 via an electrical wire set on the supporting frame 12.

Each of the mobile modules 14 includes a top surface 142, a bottom surface 144, a front surface 146, a back surface 148, a power source unit 147, and a power port 149. The top surface 142 is parallel to the bottom surface 144. The mobile modules 14 are fastened to the supporting frame 12 and arranged along a direction perpendicular to the top surface 142. The front surface 146 is parallel to the back surface 148. The front surface 146 is fastened to the fastening holes 120 via the screws 16. The power port 149 extends from the back surface 148. The power source unit 147 correspondingly connects with the rotating switch 140 via a power line 1472 and a control signal line 1470. The power source unit 147 is electrically connected to the load 2 via the power port 149. The power source unit 147 controls a rotation of the rotating switch 140 by transmitting a control signal to the rotating switch 140 via the control signal line 1470. The power source unit 147 transmits power signal from the rotating switch 140 to the load 2 via the power line 1472. The rotating switch 140 switches between a terminal of the main controller 10 and a terminal of the adjacent mobile module 14. The power source unit 147 selectively connects with the main controller 10 or the adjacent mobile module 14 according to the rotation of the rotating switch 140.

The power source unit 147 includes a power-off protection circuit 1473 electrically connected to the loads 2 and a power surveillance circuit 1474 electrically connected to the power-off protection circuit 1473. The power surveillance circuit 1474 presets a power limit according to a rated power of the load 2 connected to the mobile module 14, determines an operating power of the load 2, and controls the power-off circuit to cut off the connection with the load 2 when the operating power of the loads 2 is greater than the power limit in order to prevent the load 2 from overload damage. Because the power source unit 147 only cuts off an internal electrical connection between the mobile module 14 and the load 2, and the electrical connections between the other mobile modules 14 and the corresponding loads 2 are not affected.

In this embodiment, the rotating switch 140 includes a rotating axis 1401 set on an outer sidewall of the mobile module 14, an upper connecting arm 1402, and a lower connecting arm 1403. The upper connecting arm 1402 is substantially an elongated rod, and includes a supporting rod 1402a and a connecting projection 1402b. The supporting rod 1402a extends from the rotating axis 1401 along a radial direction of the rotating axis 1401. A length of the supporting rod 1402a is greater than a distance between the rotating axis 1401 and the top surface 142. The connecting projection 1402b perpendicularly extends from an end of the supporting rod 1402a away from the rotating axis 1401. The supporting rod 1402a and the connecting projection 1402b cooperatively form an L-shape hook. The lower connecting arm 1403 is substantially an elongated rod and extends from the rotating axis 1401 along a tangential direction of the rotating axis 1401. A length of the lower connecting arm 1403 is equal to a distance between the rotating axis 1401 and the bottom surface 144. The upper connecting arm 1402 and the lower connecting arm 1403 correspondingly extend along two opposite directions of a same line, but the upper connecting arm 1402 is deviated from the lower connecting arm 1403 a predetermined distance. The upper connecting arm 1402 and the lower connecting arm 1403 rotate around the rotating axis 1401 in a plane perpendicular to the front surface 146.

A gap between two adjacent mobile modules 14 is less than a length of a top part of the upper connecting arm 1402 extending over the top surface 142. When the rotating switches 140 of two adjacent mobile modules 14 correspondingly rotates to a position where the upper connecting arm 1402 is perpendicular to the top surface 142, the connecting projection 1402b of a lower mobile module 14 is electrically connected to the lower connecting arm 1403 of an upper mobile module 14 to connect two adjacent mobile modules 14 in series.

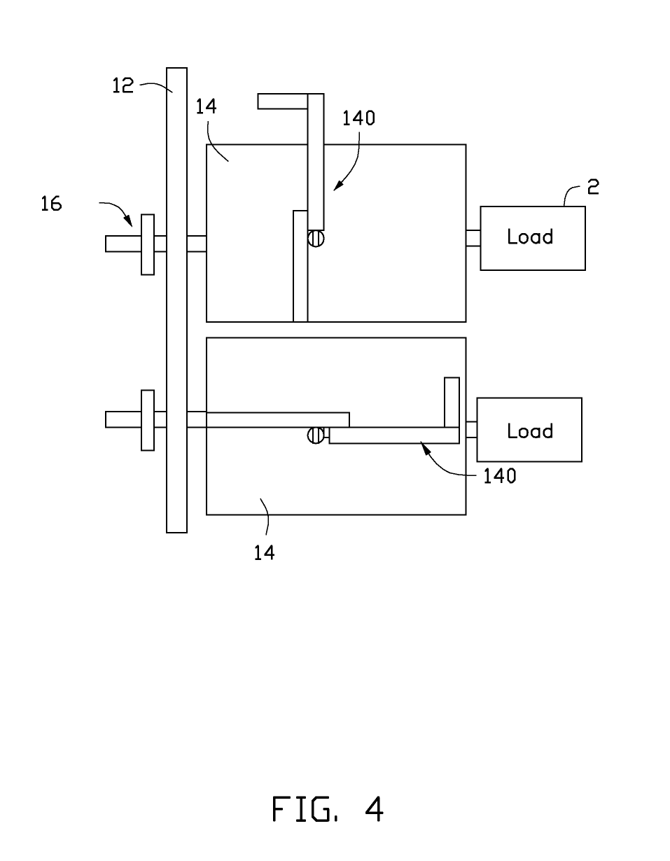

FIGS. 3 and 4 show that when the rotating switches 140 of two adjacent mobile modules 14 correspondingly rotates to a position when the upper connecting arm 1402 is parallel to the top surface 142, the upper connecting arm 1402 of the lower mobile module 14 are separated from the lower connecting arm 1403 of the upper mobile module 14. An end of each lower connecting arm 1403 contacts with the screw 16 and is electrically connected to the main controller 10 via the supporting frame 12. Therefore, when the rotating switches 140 of two adjacent mobile modules 14 rotate to the position where the upper connecting arm 1402 is parallel to the top surface 142, the adjacent mobile modules 14 are connected in parallel. The mobile modules 14 are selectively connected in series or in parallel by switching of the rotating switch 140.

In operation, the mobile modules 14 providing power to the loads 2 which are a same type, and are connected in series via the rotating switches 140. Thus, the mobile modules 14 set a same current limit to protect the loads 2 of the same type. The mobile modules 14 providing power to the loads 2 which are a different type, and are connected in parallel. Thus, the mobile modules 14 set a number of different current limits to protect the corresponding types of the loads 2, and one of the mobile modules 14 cuts off the electrical connection with the load 2 do not affect the electrical connection between the other mobile modules 14 and the corresponding loads 2.

While various exemplary and preferred embodiments have been described, it is to be understood that the present disclosure is not limited thereto. On the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A power management system, comprising:
a main controller connected to an external power source;
a pair of supporting frames extending from the main controller; and
a plurality of mobile modules removably mounted on the supporting frames and electrically connected to the main controller via the supporting frame;
wherein each of the mobile modules is connected to a load, the main controller provides power to the loads via the corresponding mobile modules, each of the mobile module presets a power limit according to a rated power of the load connected to the mobile module and cuts off an electrical connection with the load when an operating power of the load is greater than the power limit.

2. The power management system of claim 1, wherein the main controller presets a total power limit according to all the loads connected to the main controller and cuts off the electrical connection between the loads and the external power source when the total power of all the loads is greater than the total power limit.

3. The power management system of claim 1, wherein each of the supporting frames defines a plurality of evenly spaced fastening holes, the fastening holes defined on the different supporting frames are aligned with each other, each of the mobile modules is fastened to the fastening holes via at least one screw.

4. The power management system of claim 3, wherein the mobile module is electrically connected to the supporting frame via the screw.

5. The power management system of claim 3, wherein the mobile module is electrically connected to the main controller via an electrical wire set on the support frame.

6. The power management system of claim 3, wherein each of the mobile modules comprises a top surface, a bottom surface, a front surface, and a back surface, the top surface is parallel to the bottom surface, the mobile modules are fastened to the supporting frame in order and arranged along a direction perpendicular to the top surface, the front surface is parallel to the back surface, the front surface is fastened to the fastening holes via the screws.

7. The power management system of claim 6, wherein each of the mobile modules further comprises a power port, the power port is extended from the back surface, and the mobile module provides power to the load via the power port.

8. The power management system of claim 6, wherein each of the mobile modules further comprises a rotating switch and two adjacent mobile modules connect with each other via the rotating switches.

9. The power management system of claim 8, wherein each of the mobile modules further comprises a power source unit, the power source unit correspondingly connects with the rotating switch via a power line and a control signal line, the power source unit controls a rotation of the rotating switch by transmitting a control signal to the rotating switch via the control signal line, and the power source unit transmits power signal from the rotating switch to the load.

10. The power management system of claim 8, wherein the rotating switch comprises a rotating axis set on an outer sidewall of the mobile module, an upper connecting arm, and a lower connecting arm, the upper connecting arm and the lower connecting arm are correspondingly extended from the rotating axis and along two opposite directions of a same line, the upper connecting arm is deviated from the lower connecting arm a predetermined distance, and the upper connecting arm and the lower connecting arm rotate around the rotating axis in a plane perpendicular to the front surface.

11. The power management system of claim 10, wherein the upper connecting arm comprises a supporting rod and a connecting projection, the supporting rod extends from the rotating axis along a radial direction of the rotating axis, a length of the supporting rod is greater than a distance between the rotating axis and the top surface, the connecting projection perpendicularly extends from an end of the supporting rod away from the rotating axis, the supporting rod and the connecting projection cooperatively form an L-shape hook.

12. The power management system of claim 11, wherein the lower connecting arm extends from the rotating axis along a tangential direction of the rotating axis, and a length of the lower connecting arm is equal to a distance between the rotating axis and the bottom surface.

13. The power management system of claim 12, wherein a gap between two adjacent mobile modules is less than a length of a top part of the upper connecting arm extending over the top surface, when the rotating switches of two adjacent mobile modules correspondingly rotates to a position where the upper connecting arm is perpendicular to the top surface, the connecting projection of a lower mobile module is electrically connected to the lower connecting arm of an upper mobile module to make two adjacent mobile modules connect in series.

14. The power management system of claim 12, wherein when the rotating switches of two adjacent mobile module correspondingly rotates to a position when the upper connecting arm is parallel to the top surface, an end of each lower connecting arm contacts with the screw and electrically connects with the main controller via the supporting frame, and the adjacent mobile modules are connected in parallel.
